(19) United States
(12) Patent Application Publication
(10) Pub. No.: US 2024/0153858 A1
(43) Pub. Date: May 9, 2024

(54) CHIP AND ITS MANUFACTURING, MOUNTING METHOD AND PRINTED CIRCUIT BOARD

(71) Applicant: Lingxin Electronic Technology (Wuxi) Co., Ltd., Wuxi (CN)

(72) Inventor: Zhengyu YE, Wuxi (CN)

(21) Appl. No.: 18/331,789

(22) Filed: Jun. 8, 2023

(30) Foreign Application Priority Data
Nov. 8, 2022 (CN) 202211393158.0

(51) Int. Cl. H01L 23/498; H01L 21/48; H01L 23/00

(52) U.S. Cl. CPC H01L 23/49838; H01L 21/4846; H01L 24/14; H01L 24/16; H01L 2224/14163; H01L 2224/16225

(57) ABSTRACT

A chip, its manufacturing and mounting method, and a printed circuit board are disclosed. The chip comprises: a body with first and second sides opposite to one another; a packaging frame located on the first side of the body and electrically connected to the body, the exposed conductive pattern on the side of the packaging frame distal from the body matches a target pattern of the printed circuit board, and the target pattern includes the pad position of the pad and the layout of the electrical network on the target printed circuit board. The chip includes leadless chips, and the target pattern is designed for leaded chips. Through the disclosed solution, the leadless chip can be compatible with the PCB board originally designed for the chip with leads, and the universality of the chip can be improved.

### BACKGROUND

### Technical Field

The disclosure relates to the technical field of semiconductors, in particular to a chip, a method for manufacturing and mounting, and printed circuit board design.

### Description of the Related Art

Currently, there is a power distribution chip including a so-called “High-side switch” on the market. This power distribution chip integrates control circuits and power metal-oxide semiconductor field-effect transistors (MOSFETs).

In the current mainstream power distribution chip products, the power MOSFET is usually manufactured using a vertical process, and the control circuit part is manufactured using a lateral process. The package of the product adopts the package form with leads and a heat dissipation pad (thermal pad). For example, the wire bonding process is adopted, and the heat dissipation pad is connected to the highest potential (Vin). For users who use the power distribution chip manufactured in the aforementioned way, the corresponding pattern will be designed on the printed circuit board (PCB), such as setting pad position and electrical network of the lead pads on the PCB board, according to the pin (lead) position of the power distribution chip. The pad position and electrical network of the heat dissipation pad on the PCB board will be designed according to the heat dissipation pad position of the power distribution chip.

If using BCD (Bipolar-CMOS-DMOS) directly, when using a leaded package, since the BCD substrate generally is grounded, and the heat dissipation pad on the existing PCB board is usually connected to the highest potential, the potential of the two mismatch. As a result, the power distribution chip manufactured by the BCD process cannot be pin-to-pin compatible with the existing PCB on the market. Moreover, the wire bonding resistance of the BCD process is high, which affects chip performance.

If a flip-chip process is used to manufacture a chip, the resistance can be effectively reduced to overcome the defect of high resistance of the BCD process. However, the flip chip has no leads and no heat dissipation pads, so it is also not compatible to be coupled to the existing PCB boards in the market for pin-to-pin compatibility since the flip chip has no leads and no heat dissipation pads. Moreover, the package size of the flip chip is similar to the size of the chip itself, usually, the package of the flip chip is not designed to be larger in order to achieve pin-to-pin compatible with wire-bonding package, the electrical connection pattern for the flip chip is not specially designed for such compatibility, either.

For the above reasons, existing leadless chip packages may not be compatible with the PCB board originally designed for the leaded chips.

### BRIEF SUMMARY

The techniques of the disclosure make leadless chips compatible to be coupled to PCB boards designed for leaded chips.

An embodiment of the present disclosure provides a chip, comprising: a body having opposite first and second sides; a packaging frame located on the first side of the body and electrically connected to the body, the exposed pattern on the side of the packaging frame distal from the body matching the target pattern, and the target pattern includes the pad position of the pad on the target printed circuit board and the layout of the electrical network; wherein the chip includes a leadless chip, the target pattern being designed for a leaded chip.

In some implementations, the matching of the exposed pattern and the target pattern includes no electrical network conflict in the electrical network in the overlapping area of the exposed pattern of the packaging frame and the target pattern on target PCB.

In some implementations, the exposed pattern is a part of the matching pattern, and the matching pattern includes the layout of the electrical network on the packaging frame and the structure of the solder joint connection between the side of the packaging frame facing the body and the body. The matching pattern is determined according to the target pattern, and the body and the target printed circuit board are electrically connected through an electrical network provided by the matching pattern.

In some implementations, the packaging frame is a single-layer structure, and a part of the matching pattern is exposed on a side of the packaging frame distal from the body to form the exposed pattern.

In some implementations, the packaging frame is a multilayer structure, and the matching pattern includes the layout of the electrical network on each layer frame, wherein the layout of the electrical network on the outermost frame of the packaging frame forms the exposed pattern.

In some implementations, the exposed pattern is substantially consistent with the target pattern.

In some implementations, the pads include pin pads, the exposed patterns include first patterns, and the distribution of the first patterns on the packaging frame corresponds to pad positions of the pin pads.

In some implementations, the pad includes a heat dissipation pad, the exposed pattern includes a second pattern, and the second pattern falls into the pad pattern of the heat dissipation pad.

In some implementations, the packaging frame is a multilayer frame, and the layout of the electrical networks on outermost frame layers of the multilayer frame match with one or more of a pattern of the connection terminals on the body and a pattern of connection pads on a PCB board, respectively.

In some implementations, the packaging frame is a single-layer structure, and the second pattern is a matching pattern exposed on the side of the packaging frame distal from the main body, wherein the matching pattern includes an electrical pattern on the packaging frame. In the layout of the network and the structure of the solder joints connection between the side of the packaging frame facing the body and the body, the matching pattern is determined according to the target pattern. The body and the target PCB board are electrically connected by the electrical network provided by the matching pattern.

In some implementations, solder joints and electrical networks are provided on the first side of the body, and the body is electrically connected to the packaging frame through the solder joints and the electrical network.

In some implementations, the solder joints include a plurality of input voltage solder joints and a plurality of output voltage solder joints arranged alternately in an array, and the input voltage solder joints and the output voltage solder joints are arranged alternately.

In some implementations, the packaging frame includes a plurality of strip-shaped electrical networks, and the electrical networks are suitable for electrically connecting the solder joints and the pads.

In some implementations, the leadless chip includes a flip chip, and/or, the chip includes a power distribution chip.

In some implementations, the body includes: a semiconductor substrate having opposite front and back sides, the front side faces the first side of the body, and the back side faces the second side of the body; and working devices are formed on the front side of the semiconductor substrate, the packaging frame being located on the side of the working device distal from the semiconductor substrate.

Embodiment of the present disclosure also provides a chip manufacturing method, including: acquiring a target pattern, wherein the target pattern includes pad positions of pads on a target printed circuit board and a layout of an electrical network; determining the exposed pattern of the packaging frame according to the target pattern, so that the exposed pattern matches the target pattern; and electrically connecting the packaging frame to the first side of the body to obtain the chip, wherein the body has opposite first and second sides, the exposed pattern is located on the side of the packaging frame distal from the body, and wherein the chip includes a leadless chip, and the target pattern is designed for a leaded chip.

In some implementations, the matching of the exposed pattern and the target pattern includes no electrical network conflict in the electrical network in the overlapping area of the exposed pattern of the packaging frame and the target pattern on target PCB.

In some implementations, the determining the exposed pattern of the packaging frame according to the target pattern so that the exposed pattern matches the target pattern includes: determining a matching pattern according to the target pattern, wherein the matching pattern includes the layout of the electrical network on the packaging frame and the structure of the solder connection between the side of the packaging frame facing the body and the body. The body and the target printed circuit board provide the electrical network connection through the matching pattern. The exposed pattern is designed and configured based on the matching pattern.

In some implementations, the packaging frame is a single-layer structure, and the obtaining the exposed pattern based on the matching pattern includes: half-etching the packaging frame to remove part of the matching frame on the side of the packaging frame distal from the body, the remainder of the matching pattern is adapted to form the exposed pattern.

In some implementations, the packaging frame is a multilayer structure, the matching pattern includes the layout of the electrical network on each layer of the frame, and the obtaining the exposed pattern based on the matching pattern includes determining the outermost layer of the matching pattern as the exposed pattern.

In some implementations, the exposed pattern is substantially consistent with the target pattern.

In some implementations, the pads include lead pads, the exposed pattern includes the first pattern, and determining the exposed pattern of the packaging frame according to the target pattern includes correspondingly determining the layout of the first pattern on the packaging frame.

In some implementations, the pad includes a heat dissipation pad, and the exposed pattern includes the second pattern, and the determining the exposed pattern of the packaging frame according to the target pattern includes obtaining the second pattern according to the pad pattern of the heat dissipation pad and the number of layers of the packaging frame, so that the second pattern falls into the pad pattern of the heat dissipation pad.

In some implementations, the determining to obtain the second pattern according to the pad pattern of the heat dissipation pad and the number of layers of the packaging frame includes: when the packaging frame is a multilayer structure, according to the heat dissipation pad, the pad pattern of the multilayer frame determines the second pattern, wherein the second pattern includes the layout of the electrical network on the outermost frame in the multilayer frame; when the packaging frame is a single-layer structure, the packaging frame is distal from the remaining part of the matching pattern after half-etching one side of the body is determined as the second pattern, wherein the matching pattern includes the layout of the electrical network on the packaging frame and the side of the packaging frame facing the body and the solder joint connection structure of the body, the matching pattern is determined according to the target pattern, and the body and the target PCB board are electrically connected through the electrical network provided by the matching pattern.

In some implementations, electrically connecting the packaging frame to the first side of the body to obtain the chip includes setting solder joints and electrical networks on the first side of the body, and electrically connecting the packaging frame to the first side of the body through the solder joints.

Embodiment of the present disclosure also provides a chip mounting method, including: obtaining the above-mentioned chip; and obtaining a target printed circuit board, the target printed circuit board having opposite first sides and second sides. The first side of the printed circuit board is provided with the target pattern; a mask layer is provided on the first side of the target printed circuit board, the mask layer has a window opening pattern to expose part of the target pattern, the window opening pattern is matched with the exposed pattern; electrical connection material is filled in the window opening area defined by the window opening pattern, and the chip is mounted on the first side of the target printed circuit board, electrically connected to the target printed circuit board through the electrical connection material; and the chip includes a leadless chip, and the target pattern is designed for a leaded chip.

In some implementations, after the chip is mounted on the first side of the target printed circuit board, the chip mounting method further includes removing the mask layer.

In some implementations, implementing mask layer on the first side of the target printed circuit board includes: using the window opening pattern as a mask to form a mask layer on the first side of the target printed circuit board according to the window opening pattern; or, covering a stencil on the first side of the target printed circuit board, the position and size of the window opening on the stencil being determined according to the opening pattern.

Embodiment of the present disclosure also provides a printed circuit board design method including: a printed circuit board having opposite first and second sides, the first side of the printed circuit board is provided with a target pattern, the target pattern includes the pad position of the pad on the printed circuit board and the layout of the electrical network; a mask layer is arranged on the first side of the printed circuit board, and the mask layer has a window opening pattern to exposed part of the target pattern, the window opening pattern matches the exposed pattern, the exposed pattern is the layout of the electrical network exposed to the packaging frame of the chip, wherein, the exposed pattern matches the target pattern; and the chip includes a leadless chip, and the target pattern is designed for a leaded chip.

The technical solutions of the embodiments of the present disclosure have the following benefits.

Embodiment of the present disclosure provides a chip, including: a body having opposite first and second sides; and a packaging frame located on the first side of the body and electrically connected to the body, the packaging frame facing distal from body is the exposed pattern matching the target pattern, and the target pattern includes the pad position of the pad on the target printed circuit board and the layout of the electrical network; wherein the chip includes a leadless chip, and the target pattern is designed for leaded chips.

Compared with the state-of-art technology, which requires the user to adjust the electrical connection pattern on the PCB board to match the leadless chip, this implementation can make the leadless chip directly compatible to be coupled to the PCB board originally designed for the leaded chips thereby improving the university of the chip and performance, also reducing the workload on the user side. For example, although the chip is packaged without leads (leadless), the pattern and electrical network of the exposed part of the packaging frame at the bottom of the packaged chip are specially designed. Further, by matching the exposed pattern of the packaging frame with the electrical connection pattern on the target PCB, for example, the area on the target PCB with solder pads ensures that the corresponding part on the packaging frame remains exposed. Moreover, for the target PCB that is non-soldered, the area of the pad leaves the corresponding part on the packaging frame uncovered. Thus, although the chip disclosed in this embodiment is packaged by a leadless process, it can still be soldered on the pads of the customer's PCB originally designed for a leaded chip, The phenomenon of conflicting (or mismatching) electrical functions, such as an electrical short circuit or disconnection of an electrical network will be substantially reduced by the techniques of the disclosure.

Further, the leadless package may mean that no leads or pins/legs extend out after the chip is packaged. The matching of the exposed pattern of the packaging frame with the electrical connection pattern (i.e., the target pattern) on the PCB may include that there is no electrical network conflict in the overlapped area of the exposed pattern and the target pattern. For example, at the position corresponding to the pads for the original package with leads, the exposed part of the packaging frame is designed in the chip of this embodiment, the shape of the exposed part is similar to the leads, and the electrical network also corresponds to the leads. For another example, at the position corresponding to the heat dissipation pad of the package with leads, the chip of this embodiment is also designed to expose the electrical network corresponding to the packaging frame and maximize the exposed area of the electrical network. In the non-lead and non-thermal pad areas, the packaging frame cannot be exposed on the front of the chip in these areas through a targeted design such as a half-etching process, or designing the electrical network layout on the outermost frame in the multilayer packaging frame.

Embodiment of the present disclosure also provides a chip manufacturing method, including: acquiring a target pattern, wherein the target pattern includes the pad position of the pad on the target printed circuit board and the layout of the electrical network; determining the packaging frame according to the target pattern and the exposed pattern, so that the exposed pattern matches the target pattern; electrically connecting the packaging frame to the first side of the body to obtain the chip, wherein the body has an opposite first side and a second side. On the other hand, the exposed pattern is located on a side of the packaging frame distal from the body; wherein the chip includes a leadless chip, and the target pattern is designed for a leaded chip.

When manufacturing leadless chips including flip-chip technology, this embodiment considers the compatibility problem during the chip manufacturing stage, and specially designs it for compatibility considerations, such as designing packaging frame and electrical connection pattern on chip. Therefore, the leadless chip prepared by adopting this embodiment can be directly compatible with the PCB board designed for the leaded chip, the versatility of the chip is significantly improved, and the work burden on the user side is also reduced. For example, for chips that are packaged without leads, matching the exposed pattern of the packaging frame with the electrical connection pattern on the PCB, such as the area on the PCB with solder pads, ensures that the corresponding part on the packaging frame remains exposed, the non-pad area on the PCB is not exposed on the back of the chip through the half-etching process or the targeted design of the electrical network layout on the outermost frame of the multilayer packaging frame. Thus, although the chip disclosed in this embodiment is packaged by a leadless process, it can still be soldered on the pads of the customer's PCB originally designed for a chip packaged by a lead process without electrical network conflict and mismatch of electrical functions.

Embodiment of the present disclosure also provides a chip mounting method, including: obtaining the above-mentioned chip; obtaining a target printed circuit board, the target printed circuit board has opposite first sides and second sides, and the target pattern is provided on the first side of the target printed circuit board; a mask layer is provided on the first side of the target printed circuit board, the mask layer has a window opening pattern to expose part of the target pattern, the window opening pattern matches the exposed pattern; filling the window opening area defined by the window opening pattern with an electrical connection material, and mounting the chip on the first side of the target printed circuit board, wherein the chip is electrically connected to the target printed circuit board through the electrical connection material; wherein, the chip includes a leadless chip, and the target pattern is designed for a leaded chip.

This embodiment can achieve compatible mounting of the leadless chip on the target PCB designed for the leaded chip with minor process improvement and higher user operation convenience. For example, the leadless chip can be reliably mounted on the target PCB designed for the leaded chip only by adjusting the window opening pattern on the mask layer to match the exposed pattern of the chip.

Embodiment of the present disclosure also provides a prefabricated printed circuit board, including: a printed circuit board having opposite first sides and second sides, the first side of the printed circuit board is provided with a target pattern, and the target pattern includes the pad position of the pad on the printed circuit board and the layout of the electrical network; a mask layer, disposed on the first side of the printed circuit board, the mask layer has a window pattern to expose part of the target pattern, the window opening pattern matches the exposed pattern, the exposed pattern is the layout of the electrical network exposed by the packaging frame of the chip, and the exposed pattern matches the target pattern; wherein, the chip includes a leadless pin chip, the target pattern is designed for a leaded chip.

In this embodiment, a mask layer with a window opening pattern matching the exposed pattern of the leadless chip is pre-fabricated on the printed circuit board. Therefore, users does not need to adjust the mounting process to realize the compatible installation of the leadless chip on the PCB designed for the leaded chip.

### DESCRIPTION OF THE SEVERAL VIEWS OF THE DRAWINGS

FIG. 1 is the schematic diagram of a chip of the first embodiment of the present disclosure;

FIG. 2 is a sectional view along sectional line AA of FIG. 1;

FIG. 3 is a sectional view along sectional line BB of FIG. 1;

FIG. 4 is a sectional view along sectional line CC of FIG. 1;

FIG. 5 is a schematic diagram of an exposed conductive pattern of the chip shown in FIG. 1;

FIG. 6 is a schematic diagram of the window opening formed on the pad when the chip shown in FIG. 1 is installed on the target printed circuit board;

FIG. 7 is a schematic diagram of an inner packaging frame of a chip according to the second embodiment of the present disclosure;

FIG. 8 is a schematic diagram of a multilayer packaging frame of the chip shown in FIG. 7;

FIG. 9 is a sectional view along sectional line DD of FIG. 8;

FIG. 10 is a flow chart of a chip manufacturing method according to the third embodiment of the present disclosure;

FIG. 11 is a flow chart of a chip mounting method according to the third embodiment of the present disclosure; and

FIG. 12 shows a leadframe 1200 having a plurality of pre-fabricated packaging frames.

### DETAILED DESCRIPTION

Inventors recognize that the existing technology cannot achieve compatibility between leadless chips and leaded chips.

For example, a power distribution chip is a switch circuit commonly used in industries, and such chips use at least one transistor as a switch to control load on-off. According to factors like whether there is a diagnosis, the power rating, and whether it has an inductive load, a power distribution chip can be further categorized into a hot-swappable chip, a high-side switch chip, a load switch, and so on.

Taking the high-side switch chip as an example of a power distribution chip, a power distribution chip usually includes a control circuit part and one or more power MOSFETs. The control circuit part provides functions such as control and protection of the power MOSFET, and the power MOSFET is used to flow overload current. When the power MOSFET is turned on, the load current flowing through the on-resistance of the power MOSFET will cause loss and heat generation on the power MOSFET, so the high-side switch has higher requirements on heat dissipation performance. Generally, on the package, there will be a heat dissipation pad at the bottom of the chip. The heat dissipation pad of the chip is soldered to the heat dissipation pad on the PCB board provided by the user. By conducting the heat from the high-side switch to the PCB board, the high-side switch can be provided with better heat dissipation.

For the existing high-side switch, the control circuit includes multiple transistors, and a bipolar-CMOS-DMOS (BCD) technology can be used; the power part is single or multiple MOSFETs. Due to the high withstand voltage and high power, the MOSFET may be an LDMOS (lateral double-diffused MOS) having a lateral structure, or a VDMOS (vertical double-diffused MOS) or a trench MOS having a vertical structure. For the vertical structure, since the substrate is N-type (because the lower surface drain of the vertical structure is N-type, the substrate is usually also N-type), it usually needs to be connected to the highest potential of the system, that is, to Vin. The lower surface of this silicon chip also serves as the drain of the power MOSFET, and the current will flow in from the lower surface.

In some application scenarios, wire bonding may have the possible problems of high wire bonding resistance and large package size when packaging power distribution chips with leads and heat dissipation pads, and non-wire bonding packaging solutions such as flip-chip packaging chip may be used.

Leadless chip packages, e.g., a flip-chip package or a QFN chip package, may not be compatible with the PCB board originally designed for the leaded chip. Redesigning the electrical connection pattern on a PCB board to adapt to a leadless chip package, e.g., a flip-chip package, is time consuming and costly. This will obviously increase the workload on the user side and affect product promotion and application.

Embodiment of the current disclosure solves, among others, the above-mentioned technical problems. An embodiment of the present disclosure provides a chip, comprising: a body, e.g., a semiconductor die, having opposite first and second sides; and a packaging frame located on the first side of the body and electrically connected to the body, an exposed pattern of conductive material on a side of the packaging frame distal from the body matches a target pattern of connection pads on a PCB. The target pattern includes a pad position of a pad on a target printed circuit board PCB and a layout of an electrical network on the PCB. In some implementations, the chip includes a leadless chip, and the target pattern is designed for a leaded chip. In the description herein, a leadless chip (also referred to as leadless chip carrier) refers to an integrated circuit (IC) semiconductor package or a discrete semiconductor device package that has no protrusion pins for contact. A leadless chip includes exposed metal/conductive pads or areas at the outer edges and/or surfaces to establish connection with the external circuit boards, e.g., a PCB board. The exposed metal/conductive pads or areas of a leadless chip may protrude or extend beyond the rest of the edge or surface of the leadless chip. For example, an exposed metal/conductive pad of a leadless chip may extend beyond the molding compound surrounding the exposed metal/conductive pad.

From the above, this implementation scheme can make the leadless chip directly compatible with PCB boards initially designed to be used with leaded chips, thereby improving the universality of the leadless chip and reducing the cost and workload on the user side in integrating the chips with the PCB boards. For example, although the chip is packaged without leads (leadless), the pattern and electrical network of the exposed conductive parts (referred to as “exposed pattern” or “conductive pattern” for descriptive purposes) of the packaging frame at a surface, e.g., the bottom surface, of the packaged chip are designed to be electrically coupled to PCB boards. Further, the exposed conductive patterns of the packaging frame match with the electrical connection pattern (referred to as “target pattern” for descriptive purposes) on the target PCB, for example, the area on the target PCB with solder pads; portions of the packaging frame that correspond to non-pad areas of the PCB board, e.g., plastic and non-solderable area, packaging frame are encapsulated and not exposed. Thus, although a chip is packaged by a leadless technique, it can still be soldered on or otherwise electrically coupled to the connection pads of the customer's PCB originally designed for a leaded chip without the phenomenon of conflicting (or mismatching) electrical functions, such as an electrical short circuit or a disconnection in an electrical network.

Technical features and beneficial effects of the present disclosure will be more comprehensible through the illustration of example embodiments of the present disclosure described in detail herein in conjunction with the accompanying drawings.

Embodiments of the present disclosure will be described in detail with reference to the drawings. In each figure, the same reference numeral is attached to the same part. Each embodiment is just an illustration, and of course it is possible to partially replace or combine the configurations shown in different embodiments. In the modified example, descriptions of matters common to the first embodiment are omitted, and only differences are described. In particular, the same function and effect produced by the same structure will not be mentioned one by one for each embodiment.

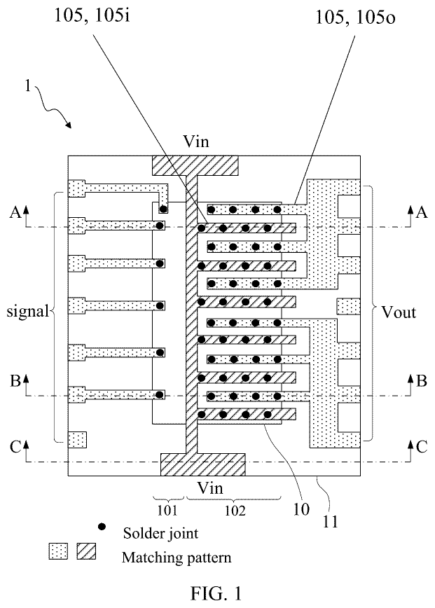

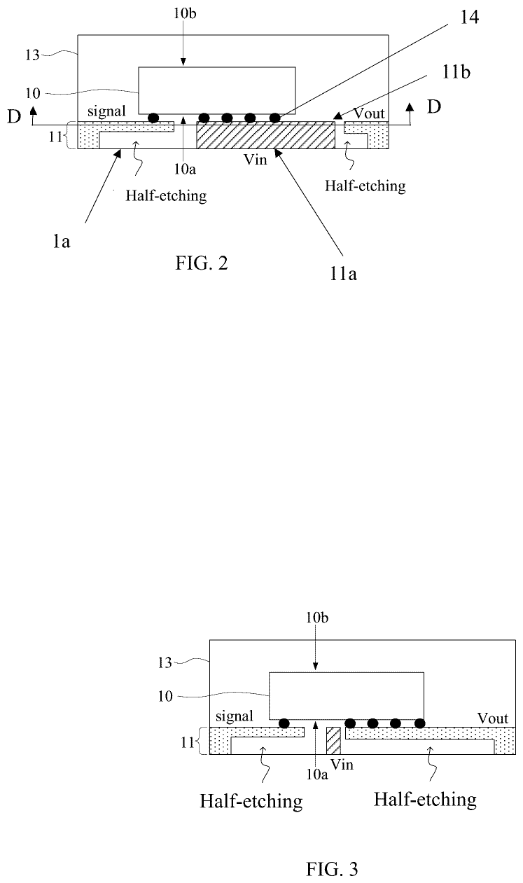

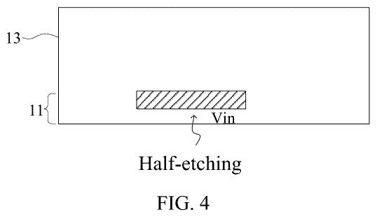

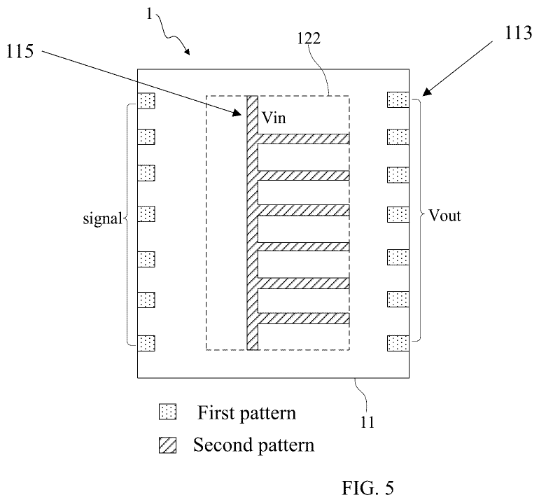

FIG. 1 is a schematic diagram of a chip 1 according to an embodiment of the present disclosure; FIG. 2 is a sectional view along sectional line AA of FIG. 1; FIG. 3 is a sectional view along sectional line BB of FIG. 1; FIG. 4 is a sectional view along sectional line CC of FIG. 1; and FIG. 5 is a schematic diagram of the exposed pattern of the chip 1 shown in FIG. 1. Among them, FIG. 1 can be regarded as a perspective or an exploded view of the chip 1 to show the internal structure of the chip 1 from the sectional line DD of FIG. 2, or when it is not plastic-encapsulated; FIG. 5 is an external view of a surface of the chip after molding. The encapsulation or molding layer 13 may be molding compounds, polymer or other plastic shell.

Embodiments are described using a flip chip or the manufacturing of the flip chip as illustrative examples. However, it should be appreciated that the techniques of the disclosure can be used with other leadless packages, like QFN, BGA, surface-mounted device, wafer-level package, embedded wafer-level BGA, etc. For example, in practical applications, this embodiment can also be used for wire-bond and flip-chip mixed chips.

Chip package or chip 1 is a semiconductor chip packaged without leads. That is, after the chip 1 is packaged, no pins or legs extend out. In some embodiments, the chip 1 does not include a heat dissipation pad at the bottom of the package.

The chip 1 may be, for example, a power distribution chip manufactured by a flip-chip process. Both FIG. 1 and FIG. 5 show a first view, or a front view, of the chip 1, and for the flip chip, the front side refers to the side of the chip 1 facing the PCB board and in contact with it when the chip 1 is installed on the PCB board. FIGS. 2-4 show the chip 1 with its face down, that is, the state of being attached onto the target PCB.

For example, referring to FIGS. 1-5, the chip 1 in this embodiment may include a body 10, e.g., a semiconductor die, and a packaging frame 11. The body 10 includes an integrated circuit or a discrete semiconductor device fabricated therein. The body 10 has a first side 10a and a second side 10b opposite to one another. The first side 10a of the body 10 faces the front surface 1a of the chip 1, and the packaging frame 11 is electrically connected to the first side 10a of the body 10.

Taking a power distribution chip as an example, the body 10 may include a control circuit 101 and a power MOSFET 102, wherein the control circuit 101 is coupled to at least one signal terminal signal, and the power MOSFET 102 is coupled to at least one voltage input terminal Vin and at least one voltage output terminal Vout.

Further, the body 10 may include: a semiconductor substrate having opposite front and back sides, wherein the front side of the substrate faces the first side 10a of the body 10, and the back side faces the second side 10b of the body 10; working devices are formed on the front side of the semiconductor substrate. The working device may include the control circuit 101 and power MOSFET 102, or other integrated circuit devices. For example, each working device may serve as a functional module of the integrated circuit contained in the chip 1. During fabrication, a working device may be formed on the front side of the semiconductor substrate to obtain the body 10.

In an illustrative example, as shown in FIGS. 1-5, the first side 10a of the body 10 may be provided with connection points 14, e.g., solder bumps, hereinafter referred to as solder bumps or solder joints, and electrical networks. The body 10 is electrically connected to the electrical network and the packaging frame 11 through these solder joints.

For example, the electrical network may include electrical connection channels between solder joints 14 and solder joints 14, between solder joints 14 and working devices, and/or between pads and pads, and may also include electrical connection channels laid out on the packaging frame 11. The electrical connection between the terminals of the working device and the pads on the target PCB can be realized through the cooperation of the solder joints and the electrical network.

In some embodiments, the electrical connection pattern formed by the solder joints and the electrical network disposed on the first side 10a of the body 10 may not be the same as the electrical connection pattern on the target PCB board (such as the target pattern described below) for an exact match. That is to say, the design of solder joints and electrical networks on the chip 1 body 10 can be more flexible, as long as it is ensured that the electrical network exposed from the working device matches to or is compatible with the corresponding exposed conductive pattern of the packaging frame 11, and exposed conductive pattern on an opposing side of the packaging frame 11 matches to or is compatible with the corresponding target solder pads on the target PCB board and the electrical networks can have a corresponding electrical path.

In some implementations, continuing to refer to FIG. 1, the pads 105 on the packaging frame 11 may include a plurality of input voltage solder joints 105i and a plurality of output voltage solder joints 105o arranged in an alternate array. Wherein, an input voltage solder joint is a solder joint electrically connected to the working device and the input voltage terminal Vin, and an output voltage solder joint is a solder joint electrically connected to the working device and the output voltage terminal Vout.

For example, the alternate array arrangement may be, for example, in the perspective shown in FIG. 1, a row of pads taken as a group, and multiple sets of input voltage pads and multiple sets of output voltage pads arranged alternately at intervals in the longitudinal direction.

In some implementations, the packaging frame 11 may include multiple sets of input voltage solder joints 105i and multiple sets of output voltage solder joints 105o arranged at intervals in two or more rows. The number of the rows or the number of the sets is not limited in this embodiment.

In some implementations, continuing to refer to FIGS. 1-5, the packaging frame 11 may be located on a side of the body 10 distal from the semiconductor substrate of the working device included in the body 10. That is, the packaging frame 11 is arranged towards the front of the chip 1, and when the chip 1 is flip-chip soldered to the target PCB board, the packaging frame 11 is located between the body 10 and the target PCB board, so that the working device is electrically coupled to the target PCB board through the packaging frame 11.

Further, the exposed conductive pattern on the side 11a of the packaging frame 11 distal from the body 10 matches the target pattern of connection pads on a PCB board (not shown), to which the chip 1 is attached. For example, front surface 1a of the chip, which includes the side 11a of the packaging frame 11, is configured to face and be coupled to the target pattern of connection pads on the PCB board.

For example, the exposed conductive pattern of packaging frame 11 may refer to the pattern formed by the part of the electrical network of the packaging frame 11 exposed on the surface of the chip 1 after plastic packaging, as shown in FIG. 5. The electrical network of the packaging frame 11 is adapted to electrically connect to solder points and pads.

The target pattern may, in some implementations, include pad positions of pads on the target PCB board and layout of electrical networks on the target PCB board. The target printed circuit board refers to the PCB board on which the chip 1 needs to be coupled to, e.g., soldered on, and the electrical connection layout on the target printed circuit board may be designed and manufactured according to the leaded chip with pins (and thermal pads). That is, the target patterns of the PCB are designed for leaded chips. The material used for the pads may be, for example, copper.

In some embodiments, the target pattern may include the layout of all pads required for soldering the chip on the target PCB and all electrical networks for electrical connections. In some embodiments, the target pattern may only capture a part of the pattern laid out on the target PCB, for example, a plurality of output voltage terminals Vout are only connected to a part of the pads on the PCB.

Electrical network described in this embodiment is not limited to the ones illustratively shown, and the layout of the electrical network may be configured due to related electrical functions of the chip 1, which is limited in the disclosure.

By acquiring the target pattern on target PCB in advance, the layout of the electrical network exposed on the bottom of the chip 1, e.g., exposed patterns of pad 105 of the packaging frame 11 are designed to match or be compatible with the target pattern on the target PCB. The matching may include that there is no conflict or mismatch in the electrical network (or electrical function) in the overlapping area of the exposed pattern of the packaging frame 11 and the target pattern on target PCB. For example, matching can include the absence of electrical shorts and opens in overlapping regions.

Further, the area where the exposed pattern of the chip 1 and the target pattern of the target PCB overlap may refer to the projection of the exposed pattern overlap the target pattern on the target PCB. After the chip 1 is coupled on the target PCB, exposed pattern of the chip 1 is in contact with the target pattern on the target PCB, where electrical connections are made.

Based on the above, this implementation scheme can make the leadless chip directly compatible with the PCB board designed for the leaded chip, thereby improving the versatility of the chip 1 and reducing the workload on the user side. For example, although the chip 1 is packaged without leads, the pattern and electrical network of the exposed part of the packaging frame 11 at the bottom of the packaged chip 1 are specially designed and configured to match with the target pattern on the target PCB. Because the exposed pattern of the pads 105 of the packaging frame 11 matches with the electrical connection pattern on the target PCB board, such as the area on the target PCB board where there is a solder pad, it is ensured that part on the packaging frame 11 that corresponds to the target pattern on the PCB board remains exposed. The areas of the packaging frame 11 that are not configured for electrical connection with the PCB board are encapsulated by the molding compound 13 and are exposed.

Thus, although the chip 1 is packaged by a leadless process, it can still be welded onto the pads of the PCB that is originally designed for a chip packaged by a lead process. Phenomena of a conflict (or mismatch) in electrical functions, such as an electrical short circuit or a disconnection of the electrical network will not occur.

The distributions of the solder joints 14 and electrical network on the body 10 of the chip 1 are also arranged correspondingly according to the electrical connection patterns on a side 11b of the packaging frame 11. Further, the packaging frame 11 is configured such that patterns of connection pads 105 on the side 11b match or are compatible for the connection with the body 10, and patterns of connection pads on the side 11a match or are compatible for the connection with the target pattern on the target PCB board, to ensure that the packaging frame 11 can be coupled to, e.g., welded onto, the target PCB board.

In a specific implementation, with continued reference to FIGS. 1-5, the exposed pattern may be a part of the matching pattern, wherein the matching pattern may include the layout of the power network on the packaging frame 11, and the side 11b of the packaging frame 11 facing the body 10 and the body 10 has a solder joint connection structure.

That is to say, the matching pattern may include the exposed conductive pattern on the side 11a of the packaging frame 11 distal from the body 10, the electrical network layout in the middle, and the solder joint connection structure between the upper layer, e.g., the side 11b of the packaging frame 11 facing the body 10, and the chip 1. Thus, the body 10 and the target PCB board are electrically connected through the electrical network provided by the matching patterns of the packaging frame 11 on opposing sides 11a, 11b.

Further, the matching patterns on opposing sides 11a, 11b of the packaging frame 11 can be determined or configured according to the target pattern on the PCB, to ensure reliable electrical connection between the working device of the chip 1 and the target PCB.

For example, the example packaging frame as shown in FIGS. 1-5 includes a single-layer structure. A part of the matching pattern is exposed on the side 11a of the packaging frame 11 distal from the body 10 to form an exposed pattern. Wherein, the single-layer structure means that the packaging frame 11 has a one-layer structure, and all electrical networks of the packaging frame 11 are arranged on the same plane, and the layout of all the electrical networks is a matching pattern. In this example, the electrical network layouts on the opposite sides 11a, 11b of the packaging frame 11 of the single-layer structure can be the same initially, and can be processed, e.g., by a half-etching process with patterning, to form respective matching patterns on both sides 11b, 11a, corresponding to the body 10 and the target PCB, respectively. After the half-etch processing, an encapsulation layer is formed and parts of the conductive pads are exposed from the encapsulation layer to form the exposed pattern that match the target pattern on the target PCB.

In some implementations, continuing to refer to FIG. 1, the packaging frame 11 may include a plurality of strip-shaped electrical networks. For example, a group of input voltage solder joints corresponds to a strip-shaped electrical network. Similarly, a group of output voltage solder joints corresponds to a strip-shaped electrical network. Thus, the resistance of the packaging frame 11 soldered in the matching pattern can be reduced.

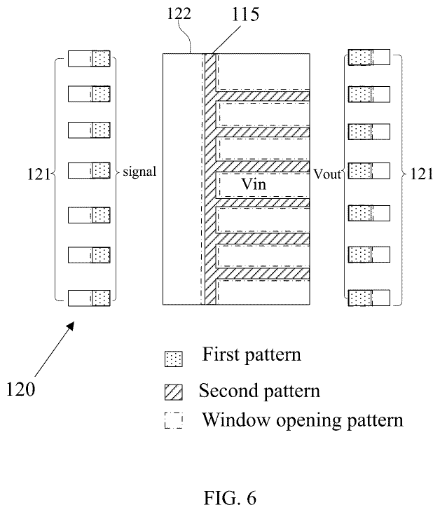

In some implementations, referring to FIG. 5 and FIG. 6, the pads on the target printed circuit board may include pin pads 121. Wherein, FIG. 6 is a schematic diagram of an opening formed on the pad 105 when the chip 1 shown in FIG. 1 is installed on the target printed circuit board.

For example, the pin pad 121 may be designed for soldering the lead (lead) of the lead chip.

Further, the exposed pattern of the packaging frame 11 may include a first pattern 113 and a second pattern 115. The distribution of the first pattern 113 on the packaging frame 11 corresponds to the position of the pin pads 121 of the target PCB.

In some embodiments, the “corresponds” or “match” may mean that, for each port or terminal of each working device on the body 10, at least one first conductive pattern is arranged on the packaging frame 11 that corresponds with lead pads that is suitable for electrically connecting.

For example, the distribution of the first patterns 113 on the packaging frame 11 and the pad positions of the lead pads 121 may be in one-to-one correspondence.

Referring to FIG. 6, multiple pin pads 121 may be provided on the target PCB 120, wherein the multiple pin pads 121 are located in two columns on both sides of the placement position of the chip 1 on the target PCB. Correspondingly, there may be multiple first patterns, and the multiple first patterns are respectively located on two sides of the main body 10 in two rows. Further, each pin pad 121 corresponds to a respective first pattern. When the chip 1 is mounted on the target PCB, each first pattern at least partially overlaps with the pad pattern of the corresponding pin pad 121. FIG. 6 is an example showing that each first pattern completely falls into the pad pattern of the corresponding pin pad 121. In some implementations, some first pattern on the packaging frame 11 and the corresponding pin pads 121 on the PCB may partially overlap, i.e., not fully overlapping.

For another example, when multiple lead pads 121 correspond to the same port, the distribution of the first pattern on the packaging frame 11 may only correspond to the pad position of one of the lead pads 121. Alternatively, the area of the first pattern can be larger to correspond to the plurality of pin pads 121 at the same time.

In some implementations, the exposed patterns 113, 115 on the packaging frame 11 match the location of the pin pads 121 on the target PCB. The shape of the exposed pattern is similar to that of the corresponding pin pads 121.

In some implementations, the first pattern 113 may also include an interference pattern, and the distribution of the interference pattern on the packaging frame 11 corresponds to an unimportant position on the target PCB, such as a position that will not interfere with the target pattern.

In some implementations, continuing to refer to FIG. 5 and FIG. 6, the pads of the PCB may include heat dissipation pads 122. For example, heat dissipation pads 122 may be designed to solder heat dissipation pads (thermal pad) for leaded package.

Further, the second pattern 115 of the exposed pattern of the packaging frame 11 may fall into the pad pattern of the heat dissipation pad 122.

Further, the distribution of the second pattern 115 on the packaging frame 11 may correspond to the pad positions of the heat dissipation pads 122 on the target PCB. That is, for each port of each working device on the body 10, at least one second pattern 115 may be arranged on the packaging frame 11 to correspond to the heat dissipation pad 122 suitable for electrically connecting the port.

In some embodiments, the number of heat dissipation pads 122 may be one and corresponds to all ports on the body 10 that need to be electrically connected to the heat dissipation pads 122. Correspondingly, the second pattern 115 can be an integral pattern and fall into the pad pattern of a single heat dissipation pad 122. In some embodiments, the second pattern may include a plurality of independent patterns, and the plurality of patterns are all located in the pad pattern of the single heat dissipation pad 122. For example, the second pattern 115 may be in a honeycomb shape, as shown in FIG. 6.

For example, a thermal pad 122 may be provided on the target PCB. A single heat dissipation pad 122 may be located between two columns of pin pads 121, for example, located directly below the corresponding position of the body 10 on the target PCB. The area of the heat dissipation pad 122 is generally not smaller than the area of the main body 10, to achieve a better heat dissipation effect. Correspondingly, when the chip 1 is mounted on the target PCB board, the second pattern of the part of the electrical network of the packaging frame 11 falls within the pad pattern of the heat dissipation pad 122.

Therefore, the chip 1 of this embodiment is also designed to expose the electrical network corresponding to the packaging frame 11 at the position corresponding to the heat dissipation pad 122 of the original package with pins, and to maximize the exposed area of the electrical network.

In some implementation, in the non-lead pad and non-thermal pad areas, an encapsulation layer is arranged to prevent the packaging frame 11 from being exposed on the front of the chip 1 in these areas, as shown in FIGS. 2-4. For example, a half-etch process can be used to recess a portion of the conductive elements of the packaging frame 11 in the non-lead pad and non-thermal pad areas. Such half-etch process also formed the exposed first patterns 113 and second patterns 115.

Therefore, by designing the pattern exposed at the bottom of the packaging frame 11 of the flip chip, it is basically consistent with the electrical network at the same position as the pin pads and/or heat dissipation pads of the leaded product, to achieve soldering compatibility.

In some implementation, referring to FIGS. 1-5, for a single-layer packaging frame 11, the second pattern may belong to a matching pattern formed on a side of the packaging frame 11 facing away from the body 10.

In some implementations, the pads that fall into the pad pattern of the heat dissipation pad 122, except for the electrical connection between pin pad 121 with body 10, are designed to connect the heat dissipation pads 122 and the body 10 as much as possible, and this part of the electrical network is determined as the second pattern 115. For example, referring to FIG. 1, the second pattern 115 may be in the shape of a comb.

Although heat dissipation pad 122 cannot be completely matched, the electrical connection area between the chip 1 and the heat dissipation pad 122 can still be increased as much as possible to ensure the heat dissipation performance.

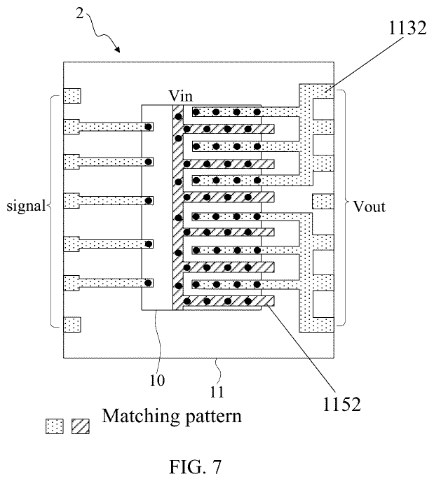

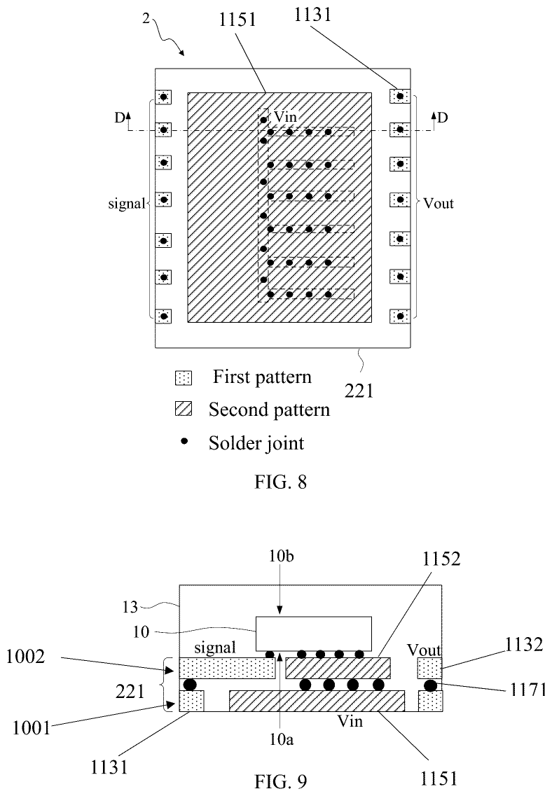

FIG. 7 is a schematic diagram of an inner packaging frame of a chip 2 according to the second embodiment of the present disclosure; FIG. 8 is a schematic diagram of a multilayer packaging frame of the chip 2 shown in FIG. 7; FIG. 9 is a cross-sectional view of FIG. 8 along sectional line DD. Here, the chip 2 and the chip 1 in the embodiment shown in FIGS. 1-5 share some similar structural features, the description of which will be omitted.

As shown in FIGS. 7-9, the electrical connection between the body 10 and the pads 121, 122 can be distributed in multiple layer (e.g., a two-layer connection structure as shown in FIG. 9), and there is an electrical connection between the two-layer structures, e.g., conductive bumps 117. In the packaging frame 221 of the multilayer connection structure, the frame of the layer distal from the main body 10 is marked as the outermost frame 1001, here the layers of the exposed patterns 1131, 1151, and the remaining layers in the multilayer structure are marked as the inner frame 1002, here layers 1132 and 1152. For example, the interconnection 1171 between two vertically adjacent layers of frames 1001, 1002 can be achieved by electroplating or placing copper bumps or using other interconnection techniques such as vias. FIG. 7 shows a schematic exploded front view of the chip 2 after removing the outermost frame, and FIG. 8 shows a schematic diagram of the electrical connection of the double-layer structure of the packaging frame 221 in the second pattern 1151.

For a multilayer structure of the packaging frame 221, the matching pattern means the layout of electrical networks in each layer, and the outer most layout is the exposed pattern.

For example, the exposed patterns 1131, 1151 formed on the outermost frame may include a first pattern corresponding to the pin pad 121 and a second pattern corresponding to the heat dissipation pad 122.

For example, the layout of the electrical network on the inner frame 1002 is configured so that the electrical network layout of the inner frame 1002 corresponds to the connection terminals of the main body 10 and the exposed patterns 1131, 1151 of the outermost frame 1001 correspond to the conductive or thermal pads 121, 122 of the target PCB.

For example, the exposed second pattern 1151 can be determined according to the pad pattern of the heat dissipation pad 122, and the layer 1152 of the inner frame 1002 does not need to correspond to the pad pattern of the heat dissipation pad 122. Instead, the pattern design of the layer 1152 of the inner frame 1002 can be configured to correspond to or be coupled to the connection terminals of the body 10.

In some embodiments, the distribution of the second pattern 1151 on the outermost frame of the packaging frame 221 can completely match the pad pattern of the heat dissipation pad 122.

That is to say, the area and position distribution of the exposed patterns 1131, 1151 on the chip 1 are basically consistent with the area of and the position distribution on the target PCB of the pin pads 121 and thermal pad 122, respectively.

In some embodiments, the distribution of the second pattern 1151 on the outermost frame 1001 of the packaging frame 221 may partially match with the pad pattern of the heat dissipation pads 122. For example, the area of the exposed pattern 1151 may be smaller than the area of the heat dissipation pad 122 on PCB 122, for example, the exposed pattern 1151 in a honeycomb shape may fall into the pad pattern of the heat dissipation pad 122.

The packaging frame 11 of the single-layer structure shown in FIGS. 1-5 give priority to avoiding electrical conflicts when designing the exposed patterns 113, 115, which may in some scenarios result in insufficient filling rate of the electrical network of the single-layer package frame 21, which may cause restrictions on the graphic design of the second pattern. In comparison, the filling rate of the electrical network in the packaging frame 221 of the multilayer structure shown in FIGS. 7-9 can be set arbitrarily with more flexibility, so while effectively avoiding electrical conflicts, the pattern design flexibility of the first pattern 1131, the second pattern 1151 is also higher.

Taking the double-layer structure packaging frame 221 shown in FIGS. 7-9 as an example, it is possible to achieve complete alignment between the chip 2 and the heat dissipation pad 122, the pin pad 121 of the target PCB, while ensuring that no electrical short circuit occurs when the chip 2 is soldered to the target PCB. Thus, a better heat dissipation performance can be obtained.

Further, considering that the inner frame of the double-layer structure of the packaging frame 221 has an electrical network connecting the pin pads 121 and the body 10, the pattern of the electrical network layer 1152 in the inner frame can be comb-shaped, similar to the second pattern 115 of the chip 1 in the embodiment shown in FIGS. 1-5, as shown in the graphic area framed by the dotted line in FIG. 8. In this way, the electrical network connection between the pin pad 121 and the body 10 will not be disturbed, and reliable electrical connection and heat dissipation between the working device in the body 10 and the heat dissipation pad 122 can be ensured.

This embodiment is illustratively shown by taking the packaging frame 221 with a double-layer structure as an example. In some embodiments, the multilayer structure of the packaging frame 221 may have a structure of three or more vertical layers or frames interconnected to one another. Correspondingly, for the outermost frame in the multilayer structure, the electrical network of the layer is designed or configured to fully align or align as much as possible with the pad patterns of the heat dissipation pad(s) 122 and/or the pin pad(s) 121; for the inner frame in the multilayer structure, it is designed to be configured so that the electrical network on the inner layer frame is successfully connected to the contact terminals of the body 10 and to the exposed patterns 1131, 1151 of the outermost frame 1001, which is connected to lead pads 121 and the heat dissipation pads 122, respectively.

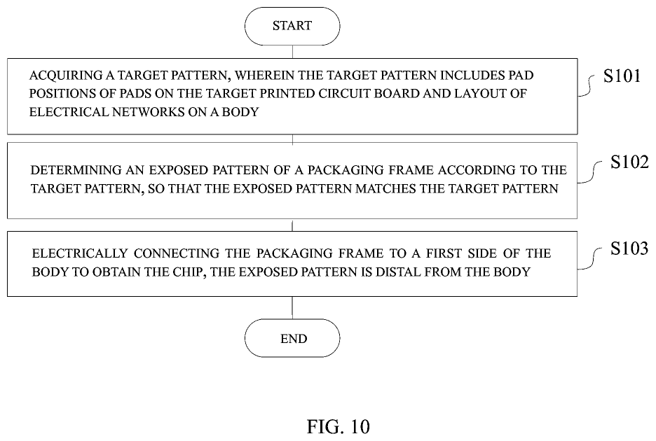

FIG. 10 is a flow chart of a chip manufacturing method according to the third embodiment of the present disclosure. This embodiment may be suitable for manufacturing the chip 1 shown in FIGS. 1-5 or manufacturing the chip 2 shown in FIGS. 7-9. Therefore, for explanations of terms involved in this embodiment, reference may be made to relevant descriptions of the embodiments shown in FIGS. 1-9, and details are not repeated here.

For example, referring to FIG. 10, the chip manufacturing method described in this embodiment may include the following steps:
Step S101, acquiring a target pattern, wherein the target pattern includes pad positions of pads on the target printed circuit board and layout of electrical networks on a body.
Step S102, determining an exposed pattern of a packaging frame according to the target pattern, so that the exposed pattern matches the target pattern.
Step S103, electrically connecting the packaging frame to the first side of the body to obtain the chip, wherein the body has opposite first and second sides, and the exposed pattern is located on the packaging frame distal from the body.

Wherein, the chip includes a leadless chip, and the target pattern is designed for a leaded chip.

In some implementations, the target pattern can be acquired in advance and stored in a preset database. Correspondingly, in step S101, the target pattern can be acquired from the preset database.

In some implementations, when step S101 is executed, the target pattern can be acquired from the target printed circuit board in real time.

In some embodiments, the target pattern may be pad locations and electrical net layouts of all pads on the target printed circuit board. Correspondingly, in step S102, the pattern of the area where the chip needs to be installed in the target pattern is intercepted, and the matching pattern is determined accordingly.

Or the target pattern may be the pad location and electrical network layout of the pads in the area where the chip is mounted on the target printed circuit board. Correspondingly, in step S102, the matching pattern is directly determined according to the target pattern.

In some implementations, the matching of the exposed pattern and the target pattern determined in step S102 may include: there is no electrical network conflict in the electrical network in the overlapping area of the exposed pattern of the packaging frame and the target pattern on target PCB. In this way, it is ensured that the chip manufactured by adopting this embodiment is suitable for the target PCB board.

In some implementations, step S103 may include setting solder joints and electrical networks on the first side of the body; and electrically connecting the packaging frame to the first side of the body through the solder joints. For example, the packaging frame is soldered to the first side of the body through solder joints, and the solder joints on the body correspond to the electrical network and the electrical network of the packaging frame to form electrical paths.

Further, after the step S103 of electrically connecting the packaging frame to the first side of the body, steps such as plastic packaging (molding) can be continued to obtain a complete chip.

In some implementations, step S102 may include the step of: determining a matching pattern according to the target pattern, wherein the matching pattern includes the layout of the electrical network on the packaging frame and the side of the packaging frame facing the body and the solder joint connection structure of the body, the body and the target printed circuit board are electrically connected through the electrical network provided by the matching pattern of the packaging frame; the exposed pattern is obtained based on the matching pattern.

For example, for a packaging frame with a single-layer structure, step S102 may further include the step of: half-etching the packaging frame to remove part of the matching pattern on the side of the packaging frame distal from the body, and the remaining part of the matching pattern is suitable for forming the exposed pattern as shown in FIGS. 2-4. In this example, the exposed pattern can be obtained by performing half-etching technology.

For another example, for a packaging frame with a multilayer structure, step S102 may further include a step of determining the layout of the electrical network on the outermost frame in the matching pattern as the exposed pattern. In this example, the exposed pattern can be arranged on the outermost frame of the packaging frame at the design stage, and correspondingly, the exposed pattern can be directly formed without half-etching and other processing. Further, in this example, the exposed pattern may be substantially consistent with, or match, the target pattern.

In some implementations, the pads may include lead or pin pads, and the exposed pattern may include a first pattern. Correspondingly, step S102 may include a step of correspondingly determining the distribution of the first pattern of an outermost frame of the packaging frame according to the pad positions of the lead or pin pads.

In some implementations, the pads may include a heat dissipation pad, and the exposed pattern may include a second pattern. Correspondingly, step S102 may include a step of determining a second pattern according to the pad pattern of the heat dissipation pad and the number of layers of the packaging frame, so that the second pattern of the outermost frame falls into the pad pattern of the heat dissipation pad. Further, the distribution of the second pattern on the packaging frame also corresponds to the position of thermal pad on the target PCB.

In some embodiments, referring to FIGS. 7-9, when the packaging frame is a multilayer structure, the second pattern can be determined according to the pad pattern of the heat dissipation pad. For example, the pad pattern of the heat dissipation pad may be directly determined as the second pattern. For another example, the second pattern can be designed according to the principle of being as close as possible to the pad pattern of the heat dissipation pad. For example, the pad pattern of the heat dissipation pad is rectangular, and the second pattern can be circular, and vice versa. For another example, the second pattern may be designed as a plurality of independent patterns, and the plurality of independent patterns is scattered and arranged in the area surrounded by the heat dissipation pad.

In some embodiments, referring to FIGS. 1-5, when the packaging frame is a single-layer structure, the remaining part of the matching pattern after half-etching the side of the packaging frame distal from the body can be determined as the second pattern. Thus, a step is formed on the side of the packaging frame distal from the body, so that the part not covered by the exposed pattern is not exposed.

Further, after the half-etching process is completed on the packaging frame, the processed packaging frame and the main body can be molded together to obtain a chip. At this time, the electrical network layout on the front of the chip exposed outside the plastic package is the exposed pattern.

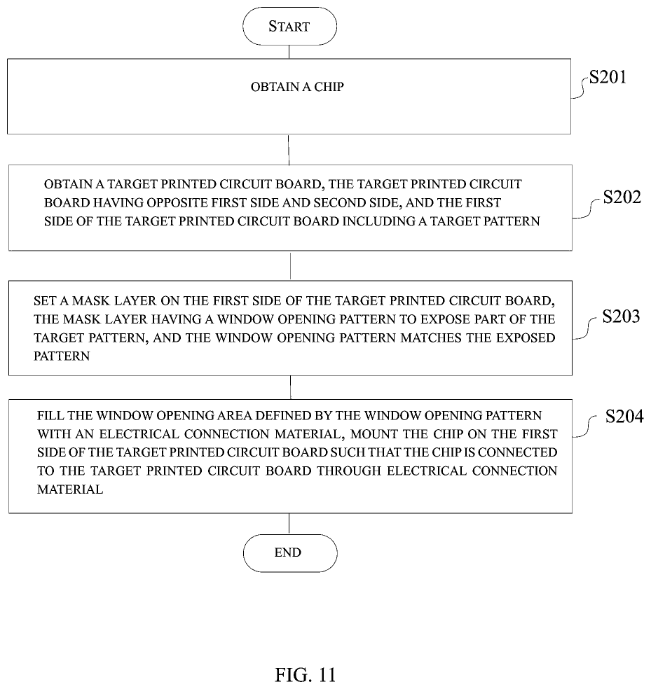

FIG. 11 is a flow chart of a chip mounting method according to some embodiments of the present disclosure. This method may be used for soldering a chip, e.g., manufactured by the method shown in FIG. 10, to the target PCB. That is, with this embodiment, it is possible to solder a leadless chip (such as chip 1 shown in FIGS. 1-5 above, or chip 2 shown in FIGS. 7-9) to a PCB board. For description purposes, reference may be made to relevant descriptions of the structures shown in one or more of FIGS. 1-9, the details of which are not repeated herein.

For example, referring to FIG. 11, the chip mounting method includes the following steps:
Step S201, obtaining the chip described in any one of the above-mentioned embodiments shown in FIGS. 1-9.
Step S202, obtaining a target printed circuit board, wherein the target printed circuit board has opposite first sides and second sides, and the first side of the target printed circuit board is provided with the target pattern.
Step S203, setting a mask layer on the first side of the target printed circuit board, the mask layer having a window opening pattern to expose part of the target pattern, and the window opening pattern matches the exposed pattern.
Step S204, filling the window opening area defined by the window opening pattern with an electrical connection material, and mounting the chip on the first side of the target printed circuit board, wherein the chip is electrically connected to the target printed circuit board through the electrical connection material.

The chip includes a leadless chip, and the target pattern is designed for a leaded chip.

In some embodiments, the electrical connection material may be, for example, solder.

Considering that the pad pattern of the pad on the target PCB may be much larger than the exposed pattern at the bottom of chip 1 (or chip 2), especially the second pattern at the bottom of chip 1 may not be a complete large piece of copper structure, and may be a sparse strip-like structure in the shape of a comb. When the chip 1 is soldered to the target PCB board, if the entire heat dissipation pad 122 is opened, problems such as a large amount of solder accumulated under the chip 1 may occur, which will affect the soldering effect. Among them, window opening means that the target PCB board is not covered by a mask layer (such as not covered by a solder mask layer or not covered by a stencil), exposing the position where the copper on the pad is used for soldering.

Therefore, in some embodiments, after the chip is manufactured by the method described in the above-mentioned embodiment shown in FIG. 10, the mask layer can be adjusted to adjust the window opening pattern on the target PCB board. For example, when the chip 1 shown in FIGS. 1-5 is mounted on the target PCB, the opening pattern on the mask layer in step S203 can be designed as the figure highlighted by dotted lines in FIG. 6.

That is to say, in this embodiment, the window opening pattern is not designed to completely match with the target pattern, but is designed according to the exposed pattern. In this way, it is ensured that there are windows on the overlapping parts of the exposed pattern and the target pattern on the target PCB, and based on this, the remaining target pattern is covered by the mask layer to avoid the large window area from affecting the soldering effect.

In some embodiments, the window opening pattern can be adjusted by fine-tuning the shape of the solder mask layer. Correspondingly, step S203 may include a step of using the window opening pattern as a mask to form a solder mask layer on the first side of the target printed circuit board.

For example, when the solder mask material is spray-painted onto the target PCB board, the window opening pattern can be used as a mask pattern, so that the first side of the target PCB board is covered by the mask pattern and not sprayed with solder mask material. That is to form a window opening pattern, which is close to the exposed pattern. Taking the area on the target PCB shown in FIG. 6 as an example, where the original pin pads 121 and heat dissipation pads 122 are not highlighted by dotted lines, these areas can be regarded as parts that do not fall into the window opening pattern, then in this example, by covering this part of the area with a solder mask, it is possible to avoid excessive solder during soldering.

For example, when step S203 is conducted, a solder mask layer can be coated on the first side of the entire target PCB board, and then chemical etching and other means are used to remove the solder mask falling into the area surrounded by the window opening pattern.

In some embodiments, the window opening pattern can be adjusted by fine-tuning the shape of the stencil. Correspondingly, step S203 may include the step of covering the first side of the target printed circuit board with a stencil, and the window opening position and window opening size on the stencil are determined according to the window opening pattern.

For example, the window opening area of the stencil can be reduced, so that when the stencil covers the surface of the target printed circuit board, the redundant part of the target pattern can be covered to reduce the amount of the solder paste.

In a specific implementation, after step S204, the chip mounting method in this embodiment may further include a step of removing the mask layer.

For example, for the scenarios where the mask layer is a solder mask layer, it can be washed away by chemical etching or other methods. For scenarios where the mask layer is a stencil, the stencil can be removed directly.

This embodiment can achieve compatible mounting of the leadless chip on the target PCB designed for the leaded chip with minor process improvement and higher user operation convenience. For example, the leadless chip can be reliably mounted on the target PCB designed for the leaded chip only by adjusting the window opening pattern on the mask layer to match the exposed pattern of the chip. Since there is no need to redesign the pattern of copper on the surface of the target PCB (that is, the target pattern), it is a minor change for the customer.

In some implementations, the mask layer may be prefabricated on the PCB board (i.e., the aforementioned target PCB board), and the prefabricated intermediate product can be called a prefabricated printed circuit board.

For example, when preparing the PCB board, when the solder mask layer is applied, the required window opening pattern can be selected for corresponding production, to obtain a prefabricated PCB board conforming to the exposed pattern of the leadless chip of this embodiment.

For example, the process flow for preparing the PCB board can follow the existing process, that is, the pattern of the pads on the prepared PCB board is still as shown in the area framed by the solid line in FIG. 6. Further, before the PCB leaves the factory, a stencil can be pasted on the first side of the PCB, and the window opening position and window opening area on the stencil are determined according to the window opening pattern. In this way, a PCB prefabricated product conforming to the exposed pattern of the leadless chip of this embodiment can also be obtained.

Correspondingly, step S202 and step S203 may be replaced by the step of obtaining a prefabricated printed circuit board. Compared with the above-mentioned embodiment shown in FIG. 11, when mounting the chip, a mask layer needs to be set first and then soldered. In this embodiment, the window opening pattern is pre-prepared on the printed circuit board to match the exposed pattern of the leadless chip. The mask layer further facilitates the installation operation. For example, the user can respectively obtain the chips shown in FIGS. 1-9 and the prefabricated printed circuit board described in this embodiment, and then solder directly.

In this way, the customer can mount the leadless chip on the PCB designed for the leaded chip with minor adjustment.

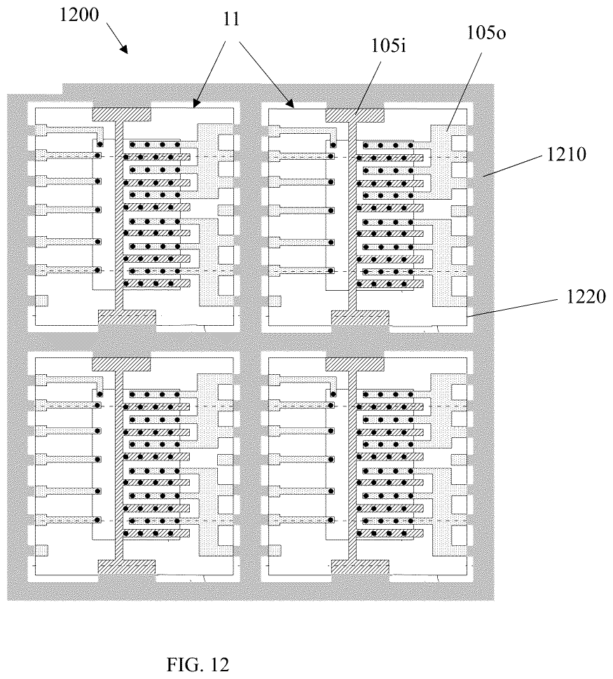

FIG. 12 shows a leadframe 1200 having a plurality of prefabricated packaging frames 11. For illustrative purposes, the packaging frames 11 of the leadframe 1200 are shown with the exploded view similar to that of FIG. 1. For each of the plurality of packaging frames 11, the edge portions of the conductive patterns, e.g., the edge portions of the pads 105i and 105o, are integral to the frame structure 1210, which is a same conductive material as the conductive patterns of the packaging frames 11. Various conductive patterns and electrical networks of the packaging frames 11, as illustratively shown in FIGS. 1-5 and 6-9 are prefabricated as parts of the leadframe 1200. Each of the plurality of packaging frames 11 are separated from the adjacent frame structure 1210 for assembly or packaging with the respective body 10 or after the assembly or packaging with the respective body 10. For example, a plurality of bodies 10 may be coupled to respective one of the pluralities of packaging frames 11 and encapsulated together, and then each be severed from the leadframe 1200 through the separation lines 1220. For another example, each packaging frame 11 may be first severed from the leadframe 1200 through the separation lines 1220, positioned on a carrier wafer, among a plurality of other packaging frames, and packaged with a respective body 10.

Although the present disclosure is disclosed above, the present disclosure is not limited thereto. Any person skilled in this technical field can make various changes and modifications without departing from the spirit and scope of the present disclosure, so the protection scope of the present disclosure should be based on the scope defined in the claims.

1. A device, comprising:
a body having a first side and a second side opposite to one another; and
a packaging frame on the first side of the body and electrically connected to the body, the packaging frame including an exposed conductive pattern of conductive material on a side of the packaging frame distal from the body,
wherein the exposed conductive pattern matches a target pattern of one or more of a pin pad or a thermal pad on a target printed circuit board (PCB).

2. The device according to claim 1, wherein the exposed pattern is a part of a conductive pattern, and the conductive pattern includes a layout of an electrical network on the packaging frame, and the body and the target PCB are electrically connected through the electrical network.

3. The device according to claim 1, further comprising a solder joint connection structure between the packaging frame and the body.

4. The device according to claim 2, wherein the packaging frame is a single-layer structure, and the exposed conductive pattern is a part of the matching pattern that is exposed on the side of the packaging frame distal from the body.

5. The device according to claim 2, wherein:
the packaging frame is a multilayer structure having multiple layers,
the multiple layers include an outermost layer that is distal from the body and an inner layer between the outermost layer and the body,
the matching pattern includes a conductive pattern on each layer of the multiple layers, and
the exposed conductive pattern is a part of the conductive pattern of the outermost layer of the packaging frame.

6. The device according to claim 5, wherein the exposed pattern of the packaging frame substantially matches the target pattern on the target PCB.

7. The device according to claim 1, wherein the target PCB includes a plurality of pin pads and the target pattern includes a pad pattern of the plurality of pin pads on the target PCB, and wherein the exposed conductive pattern includes a first pattern, the distribution of the first pattern on the packaging frame matching the pad pattern of the plurality of pin pads on the target PCB.

8. The device according to claim 1, wherein the target PCB includes the thermal pad and the target pattern includes a pad pattern of the thermal pad on the target PCB, and wherein the exposed conductive pattern includes a second pattern, the second pattern falling into the pad pattern of the thermal pad on target PCB.

9. The device according to claim 8, wherein the packaging frame is a multilayer structure including multiple layers, the second pattern of the packaging frame is configured according to the pad pattern of the thermal pad, and the second pattern includes a layout of an electrical network on a surface of the packaging frame distal to the body.

10. The device according to claim 1, wherein the first side of the body includes electrical network, and the body is electrically connected to the packaging frame through solder joints between the electrical network and the packaging frame.

11. The device according to claim 10, wherein the solder joints include a plurality of input voltage solder joints and a plurality of output voltage solder joints arranged in alternating arrays, and the input voltage solder joints and the output voltage solder joints are arranged alternately.

12. The device according to claim 11, wherein the packaging frame comprises a plurality of strip-shaped conductive patterns in contact with the solder joints.

13. The device according to claim 1, wherein the body comprises:
a semiconductor substrate having opposite front and back sides, the front side of the semiconductor substrate facing the first side of the body, and the back side of the semiconductor substrate facing the second side of the body; and
a semiconductor device formed on the front side of the semiconductor substrate,
wherein the packaging frame is located on a side of the semiconductor device distal from the semiconductor substrate.

14. A device, comprising:
a semiconductor die having a first side and a second side opposite to one another, the first side of the semiconductor die including connection terminals; and
a packaging frame including a first layer of a first conductive pattern and a second layer of a second conductive pattern, the first conductive pattern exposed on a first surface of the packaging frame that faces the first side of the semiconductor die, and the second conductive pattern exposed on a second surface of the packaging frame opposite to the first surface,
wherein the first conductive pattern includes a layout configured to overlap with the connection terminals on the first side of the semiconductor die, and
the second conductive pattern includes a second layout that matches a target pattern of one or more of a pin pad or a thermal pad on a target printed circuit board (PCB) to be coupled to the second surface of the packaging frame.

15. The device according to claim 14, wherein the first conductive pattern and the second conductive pattern includes a same conductive material.

16. The device according to claim 14, wherein the packaging frame includes interconnection structures between the first conductive pattern and the second conductive pattern, the interconnection structures coupled to the first conductive pattern and the second conductive pattern.

17. The device of claim 14, further comprising the target PCB coupled to the packaging frame, wherein the second layout of the second conductive pattern includes a portion that substantially match with the thermal pad of the target PCB.

18. The device of claim 17, wherein the target PCB is soldered to a second conductive portion.

19. A method, comprising:
obtaining a target pattern of a target printed circuit board, wherein the target pattern includes pad positions of a conductive pad on the target printed circuit board and layout of electrical network;
configuring an exposed pattern of a packaging frame according to the target pattern, so that the exposed pattern matches the target pattern; and
making a leadless chip by electrically coupling the packaging frame to a first side of a body, wherein the body has connection terminals on the first side of the body,
wherein the target pattern is designed for a leaded chip.

20. The method according to claim 19, wherein the configuring the exposed pattern comprises configuring the exposed pattern such that there is no conflict or mismatch in the electrical network in an area of the exposed pattern that overlaps the target pattern on target PCB.
